(19) United States
(12) Patent Application Publication
(10) Pub. No.: US 2026/0266556 A1
(43) Pub. Date: Sep. 10, 2026

(54) HEAT MANAGEMENT MEDIUM COMPLETELY FILLED WITH OPEN POROUS MATERIAL

(71) Applicant: INDUSTRY FOUNDATION OF CHONNAM NATIONAL UNIVERSITY, Gwangju (KR)

(72) Inventors: Ki Ju KANG, Damyang-gun, Jeollanam-do (KR); Tong Beum KIM, Incheon (KR); Yixiang WANG, Taizhou City, Zhejiang (CN); Yoon Chang JEONG, Gwangju (KR)

(73) Assignee: INDUSTRY FOUNDATION OF CHONNAM NATIONAL UNIVERSITY, Gwangju (KR)

(21) Appl. No.: 19/166,696

(22) PCT Filed: Mar. 30, 2023
(86) PCT No.: PCT/KR2023/004312

§ 371 Date: Sep. 18, 2025

(30) Foreign Application Priority Data
Mar. 23, 2023 (KR) 10-2023-0037743

(51) Int. Cl. F28D 15/04; F28F 21/08

(52) U.S. Cl. CPC F28D 15/046; F28F 21/081; F28F 21/089

(57) ABSTRACT

A heat management medium having functions of heat exchange, transfer, absorption or storage, and shock absorption, includes: an open porous material with a hydrophilic treatment on a pore surface; a thin film envelope attached to the outside of the open porous material to seal the open porous material in a vacuum state; and a working fluid filling pores of the open porous material. The open porous material has a structure that completely fills an internal space partitioned by the thin film envelope, and simultaneously acts as a moving medium for liquid and gaseous working fluids.

### CROSS-REFERENCE TO PRIOR APPLICATIONS

This application is a National Stage Patent Application of PCT International Application No. PCT/KR2023/004312 (filed on Mar. 30, 2023), which claims priority to Korean Patent Application No. 10-2023-0037743 (filed on Mar. 23, 2023), which are all hereby incorporated by reference in their entirety.

### BACKGROUND

The present disclosure relates to a heat management medium in which various thermal management functions related to exchange, transmission, absorption, storage, and thermal shock mitigation are performed by the phase change and movement of a working fluid contained within a vacuum chamber. In particular, the heat management medium is a lightweight medium having a structure in which a thin-film type open porous material with a hydrophilic envelope is sealed in a vacuum state, and in which a working fluid is injected into 10 to 80% of the internal space under vacuum.

Heat pipes are an example of a heat transfer medium that does not rely on simple conduction heat transfer and forced or natural convection. Designed for efficient heat transfer, heat pipes are used not only in various industrial heat exchangers but also widely used to connect electrical devices, such as computers, where the space around the heat source is limited and cooling devices are difficult to attach, to external cooling devices. FIG. 1 illustrates the most commonly used type of heat pipe. In the heat pipe of FIG. 1, an evaporator and a condenser are disposed at both ends of a tubular vacuum chamber, with a passageway for the working fluid provided between them. A wick, which serves as a storage and transport medium for the liquid working fluid, is formed primarily on the walls of the vapor chamber, spanning the entire area of the evaporator, condenser, and the passageway between them, with a central void space between the walls. In this case, the central void space of the passageway constitutes a passageway for the gaseous working fluid to move from the evaporator to the condenser.

The operation of the heat pipe according to FIG. 1 will be explained. When the evaporator comes into contact with a high-temperature heat source, the liquid working fluid stored in the wick vaporizes, and the gaseous working fluid is pushed along the empty space in the center of the passageway to the condenser on the opposite side as the pressure increases. Since the temperature of the condenser is relatively lower than that of the evaporator, the gaseous working fluid condenses and changes back into a liquid state. The liquid working fluid is returned to the original evaporator along the wick provided on the wall of the passageway by capillary action. As this vaporization and condensation of the working fluid are repeated, a thermodynamic cycle is completed that moves between both ends of the heat pipe, so that heat is transferred much faster than by simple conduction. Therefore, the temperature difference along the length of the heat pipe is reduced. A heat pipe that operates on this principle is called a capillary-driven heat pipe because the liquid working fluid turns to the origin along the wick by capillary action, or a vacuum chamber type heat pipe because the phase transformation of vaporization/condensation is easy even at low temperatures due to a drop in internal pressure.

In the capillary-driven heat pipes, the liquid working fluid is stored using the wick as a medium or moved by capillary action. This wick is traditionally provided in the form of sintered powder metal, metal fabric (textile or mesh), and grooves machined into the wall surface, as illustrated in FIG. 2. However, most conventional capillary-driven heat pipes have been designed based on the assumption that the wick simply functions as a medium for storing and moving the liquid working fluid. Specifically, in conventional heat pipes, the wick has pores that are small enough to facilitate capillary action, but the porosity, which is the proportion of the internal empty space, is on the order of 10 to 50%. Moreover, when the working fluid is completely liquefied, the volume is manufactured to be on the order of 20% of the total internal space of the heat pipe. Therefore, the amount of working fluid injected inside is very small, and there is a limit to increasing the transferable heat capacity, which is a measure of heat pipe performance.

Meanwhile, in cases where a lot of heat is generated in a narrow area, such as a computer's CPU or GPU, a plurality of ordinary bar-shaped heat pipes, as illustrated in FIG. 3, may be used to transfer heat to a large-capacity forced convection heat exchanger. However, this method makes the device complex and bulky. For this reason, a flat-plate vapor chamber as illustrated in FIG. 4 may be used instead of the multiple bar-shaped heat pipes as illustrated in FIG. 3. Hereinafter, unless otherwise specified, the vapor chamber refers to the “flat-plate type” as illustrated in FIG. 4. The vapor chamber is widely used to primarily transfer heat from a heat source to a wider area and then transfer the heat to a large-capacity forced convection heat exchanger. This vapor chamber may be regarded as a two-dimensional extension of the one-dimensional heat transfer of a heat pipe. In other words, the vapor chamber plays a role in transferring heat from one point to a wide surrounding area. FIG. 4, (a) is a schematic diagram illustrating the operating principle of a vapor chamber, and FIG. 4, (b) illustrates an example in which a vapor chamber is attached to a heat sink having the same floor area.

A typical vapor chamber consists of a flat plate envelope, and like a typical heat pipe, the vapor chamber has a structure in which the wick is disposed on the inner surface of the envelope, but support elements such as pillars and ribs are separately formed inside it to prevent the collapse of the flat plate envelope. In addition, sintered powder metal is widely used as the wick of the vapor chamber, just like in the case of heat pipes (References [1] X. Ji, J. Xu, A. M. Abanda, Copper foam based vapor chamber for high heat flux dissipation, Exp. Therm. Fluid Sci. 40 (2012) 93-102.), [3] M. Wang, W. Cui, Y. Hou, Thermal spreading resistance of grooved vapor chamber heat spreader, Appl. Therm. Eng. 153 (2019) 361-368.).

Recently, the demand for much thinner flat heat pipes or vapor chambers than conventional ones has been increasing for cooling mobile devices. Against this backdrop, Ji et al. proposed a vapor chamber structured in which cones are regularly disposed and formed on a flat plate using a powder composed of copper particles with a diameter of 1 micrometer (μm) and a simple flat plate is covered on top of them (FIG. 5, (a)), and the total thickness of the vapor chamber is 3.4 mm (Reference [2] Ji, X. B.; Xu, J. L.; Li, H. C.; Huang, G. H. Switchable Heat Transfer Mechanisms of Nucleation and Convection by Wettability Match of Evaporator and Condenser for Heat Pipes: Nanostructured Surface Effect. Nano Energy 2017, 38, 313-325). In addition, Yang et al. proposed a structure in which parallel grooves were dug on a silicon wafer using MEMS technology, and a number of pillars (pin-fin) were arranged in a regular pattern (array) above the grooves, and then a simple flat plate was covered above the pattern (FIG. 5, (b)), and the total thickness was 1.5 mm (Reference [3] Yang, K. S.; Lin, C. C.; Shyu, J. C.; Tseng, C. Y.; Wang, C. C. Performance and Two-Phase Flow Pattern for Micro Flat Heat Pipes. Int. J. Heat Mass Transfer 2014, 77, 1115-1123).

As an example of a very thin flat plate heat pipe or vapor chamber similar to FIG. 5, Lewis et al. proposed a structure with a total thickness of 0.5 mm by placing a copper fabric on a flat thin plate and covering a separate thin plate with copper pillars arranged in a regular pattern using MEMS technology and electroplating (Reference [4] Lewis, R.; Xu, S. S.; Liew, L. A.; Coolidge, C.; Yang, R. G.; Lee, Y. C. Thin Flexible Thermal Ground Planes: Fabrication and Scaling Characterization. J. Microelectromech. Syst. 2015, 24 (6), 2040-2048). Moreover, Tang et al. proposed a structure with a wick thickness of 0.24 mm and a total thickness of 0.5 mm by compressing a copper fabric woven into a tube shape and placing the copper fabric in the center of a similarly compressed copper tube so that the copper fabric acts as both a wick and a support for the flat plate, and the space on both sides of the copper fabric acts as the movement passageway of the vapor (Reference [5] Tang, Y.; Tang, H.; Li, J.; Zhang, S. W.; Zhuang, B. S.; Sun, Y. L. Experimental Investigation of Capillary Force in a Novel Sintered Copper Mesh Wick for Ultra-Thin Heat Pipes. Appl. Therm. Eng. 2017, 115, 1020-1030). Most recently, in 2021, Luo et al. proposed a flat plate heat pipe in which a 100 μm thick dendrite layer was formed on one surface of two copper foils through copper electroplating, and then a support plate with multiple parallel strip-shaped perforations was placed between them so that the dendrite plating layer served as a wick and the strip-shaped perforations of the support plate served as a vapor passage, with a total thickness of 0.5 mm (Reference [6] J. L. Luo, D. C. Mo, Y. Q. Wang, and S. S. Lyu, Biomimetic Copper Forest Wick Enables High Thermal Conductivity Ultrathin Heat Pipe. ACS Nano, 2021, 15, 6614-6621). However, since this method uses electroplating, the formation of dendritic tissue is sensitive to the distance and arrangement between the electrodes, so the method may not be applied when the shape of the wick in the heat pipe is not flat.

However, all of the vapor chambers of the aforementioned structure are manufactured by preparing the envelope and the wick separately and then joining the envelope and the wick, or by preparing the upper and lower plates, each having the envelope and the wick, separately and then joining them, which is disadvantageous in terms of manufacturing cost and time. In addition, in order to prevent the flat envelope from collapsing due to negative pressure caused by vacuum, a separate support element must be provided, or a wick of a special shape should be designed to also serve as the support element, so the manufacturing cost is high and furthermore, it is difficult to manufacture the product in an arbitrary shape.

Recently, the inventors of the present application proposed an ultra-light heat pipe manufactured by manufacturing a polymer template having a free shape and size by 3D printing or other methods, forming a first non-permeable electroless plating layer of uniform thickness on the surface of the template, etching the polymer inside to manufacture an ultra-light thin film structure made of the first electroless plating layer, and configuring the thin film structure as the envelope, while forming a porous second electroless plating layer on the surface of the envelope, and performing a hydrophilic treatment such as a blackening treatment on the porous second electroless plating layer to configure it as a wick of a heat pipe (FIG. 6), and confirmed that the heat pipe according to the model may have a capillary force sufficient to be applied to a capillary-driven heat pipe. FIG. 6, (a) and (b) are schematic diagrams illustrating the process for manufacturing the ultra-light heat pipe from a rod having a circular cross section and a polymer template having a hole shape, respectively, and FIG. 6, (c) illustrates a comparison of a heat pipe manufactured by this method with a commercial product manufactured by a conventional method. The heat pipe manufactured in this way is not only simple and easy to manufacture, but also has a very thin electroless plating layer as the materials of the envelope and the wick with a uniform thickness regardless of the position or direction in three-dimensional space. Therefore, the heat pipe may be made small and lightweight and may be implemented in a free-form external shape, which may be advantageously applied to mobile devices (Reference [7] Lee Yong-ju, “Realization of an ultra-light heat pipe using electroless plating”, Chonnam National University Graduate School, Master's thesis, 2023). However, even in the heat pipe with this structure, since the envelope is extremely thin, the heat pipe may not withstand the internal vacuum pressure unless the heat pipe has a circular cross-section, making it difficult to manufacture the heat pipe in a free-form external shape such as a flat plate.

In addition, most of the traditional heat pipes as well as the various vapor chambers known in the past mentioned above have a complicated manufacturing process and only serve to quickly transfer heat, so the heat pipes ultimately have limitations in that they require a heat dissipation device through forced convection, such as cooling fins and external fans. In addition, as small components such as CPU and GPU of the computer become more high-performance and the use of high heat sources in a small area, such as high-capacity secondary batteries and fuel cells increases, the devices for cooling the components and the casings for storing the components are also becoming larger and heavier, which is a major obstacle to miniaturizing and lightweighting electronic products such as mobile devices.

### SUMMARY

The present disclosure has been devised to solve the problems of the above-mentioned prior art, and provides a new concept of heat management medium that may perform various thermal management functions related to rapid heat exchange, transfer, absorption or storage, and thermal shock mitigation while acting as an ultra-light structural material that may withstand internal vacuum pressure and external load.

Under the above-described background, the inventors of the present application recently discovered and recognized the following three major facts, which are the basis of the present disclosure, in the process of studying the heat transfer characteristics of a structure in which a foam metal and the outer surface of the foam metal are sealed with a thin film envelope. (1) First, when an open foam metal with an appropriate cell size according to the structure is chemically treated to make the foam metal hydrophilic, the foam metal may serve not only as a wick and storage space for a liquid working fluid but also as a flow path for a gaseous working fluid. (2) Second, when an envelope with a thickness of several tens of micrometers is laminated on the outer surface of the foam metal according to the structure, the foam metal may also serve as an ultra-light structural material that may sufficiently withstand the vacuum and vapor pressure acting inside as well as the load applied from the outside. (3) Third, while traditionally, working fluids in heat pipes and vapor chambers have been used simply as a medium for heat transfer, the structure may utilize the high specific heat properties of the liquid working fluid compared to solids and the high latent heat properties during the phase change process, so that the use may be expanded to include heat absorption or storage. Based on these findings and knowledge, the inventors of the present disclosure have proposed a new heat management medium that may serve as an ultra-light structural material while also performing various thermal management functions such as heat exchange, transfer, absorption or storage of heat, and shock mitigation, thereby minimizing the separate use of a forced convection cooling device, thereby complying with the recent trend toward miniaturization and lightweighting of products. The gist of the present disclosure is as follows, which is the same as the claims.
(1) A heat management medium having functions of heat exchange, transfer, absorption or storage, and shock absorption, the heat management medium including: an open porous material with a hydrophilic treatment on a pore surface; a thin film envelope attached to the outside of the open porous material to seal the open porous material in a vacuum state; and a working fluid filling pores of the open porous material, in which the open porous material has a structure that completely fills an internal space partitioned by the thin film envelope, and simultaneously acts as a moving medium for liquid and gaseous working fluids.
(2) The heat management medium of (1), in which 10 to 80% of the internal space partitioned by the thin film envelope is filled with the working fluid in a liquid state.
(3) The heat management medium of (1), in which the open porous material is any one of an open foam metal, a microarchitectural material, a three-dimensional truss-shaped porous material, or a woven metal material.
(4) The heat management medium of (3), in which the working fluid is water, and the open porous material is a foam metal having a porosity of 90% or more.
(5) The heat management medium of (3), in which the working fluid is water, and the open porous material is a foam metal having a pore size of 0.3 to 1.5 mm.
(6) The heat management medium of (1), in which the envelope is a thin plate attached by means of resin bonding, welding, soldering, or brazing.
(7) The heat management medium of (1), in which the envelope is formed by a plating layer formed on the outer surface of the open porous material in a state of filling pores of the open porous material with a temporary filler made of a polymer material, and the temporary filler is removed after the plating layer is formed.
(8) The heat management medium of (1), in which the envelope is made of metal.

The heat management medium according to the present disclosure has the following advantageous effects.

First, the heat management medium has a structure in which the outer surface of the open porous material is surrounded by the envelope of a thin plate, so that the heat management medium can be implemented as an extremely lightweight structural material, and yet guarantees sufficient structural strength to withstand high internal vacuum pressure and external loads. Accordingly, even though the heat management medium has a two-dimensional flat plate-like shape similar to a conventional vapor chamber, unlike the conventional vapor chamber, there is no need to provide separate support elements such as pillars or columns inside to prevent collapse or constriction due to high internal vacuum pressure, so that manufacturing is simple and the product's outer shape can be freely designed.

Second, since the envelope of the heat management medium is very thin, rapid heat transfer to the outside by conduction is possible, and since the pores of the open porous material have a predetermined, uniform size and the surface is hydrophilic, the heat management medium can function as a moving medium for not only traditional liquid working fluids but also gaseous working fluids. Accordingly, each function of the heat management medium, such as exchange, transmission, absorption, and storage, is autonomously determined according to the operating environment related to the size and external shape of the heat management medium, the amount and location of heat input, or the like, thereby maximizing the utilization of the internal space of the heat management medium, and there is no need to design each unit of the heat management medium differently or separately for each function, so there is a high degree of freedom in product design.

Third, since the heat management medium can accommodate a significantly larger amount of working fluid internally and thus has a high transferable heat capacity, the resulting thermal shock can be effectively mitigated when momentary overheating occurs, and the problem of working fluid dry-out or depletion can be effectively suppressed even in operating environments requiring high heat capacity. As a result, the heat management medium can be expanded in the use and efficiency can be improved, in addition to the functions as the conventional heat pipe related to heat exchange and transfer, to include functions such as heat absorption or storage and shock absorption.

Fourth, as mentioned above, due to the structural characteristics of the heat management medium, especially those mentioned in the first and second points above, the heat management medium can be freely manufactured in the shape of the product without damaging each function.

### BRIEF DESCRIPTION OF THE DRAWINGS

FIG. 1 is a structural diagram of a conventional capillary-driven heat pipe.

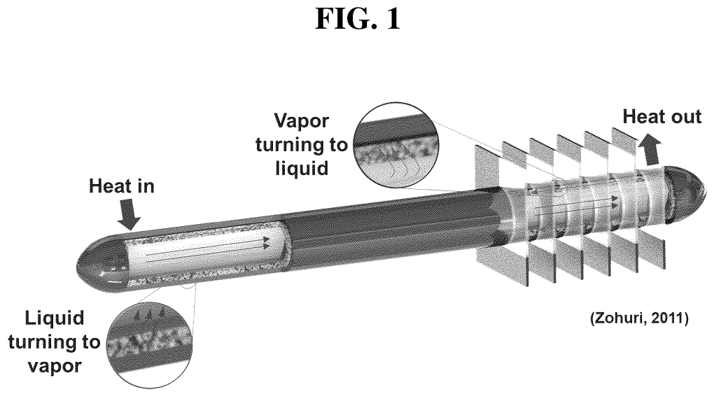

FIG. 2 is an exemplary diagram of a wick structure of the conventional capillary-driven heat pipe.

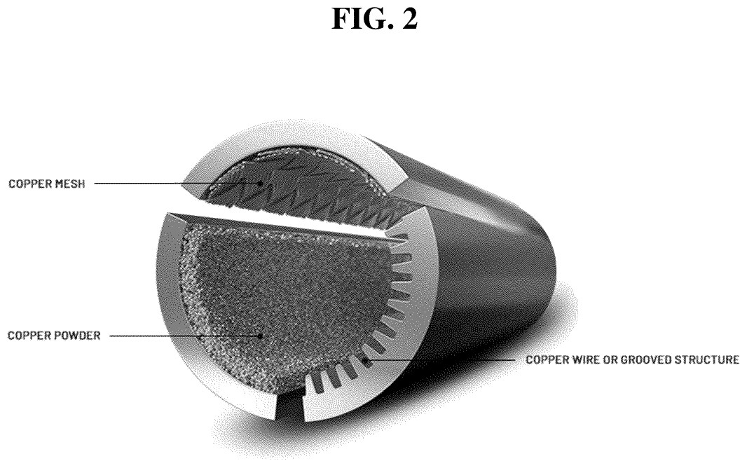

FIG. 3 is an exemplary diagram of the conventional capillary-driven heat pipe applied to an electronic component.

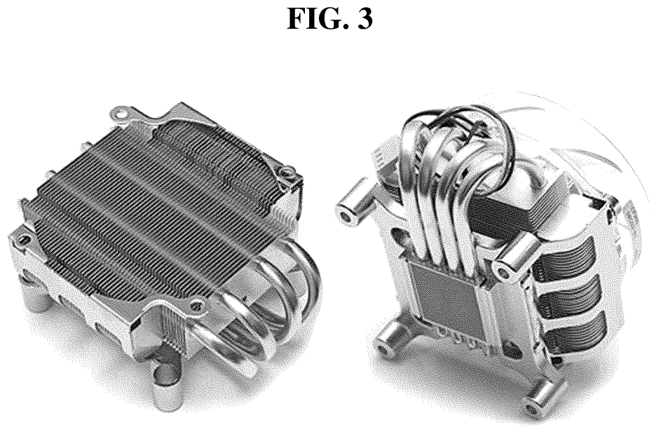

FIG. 4 is a schematic diagram of the operating principle of a conventional vapor chamber and an example photo of an application.

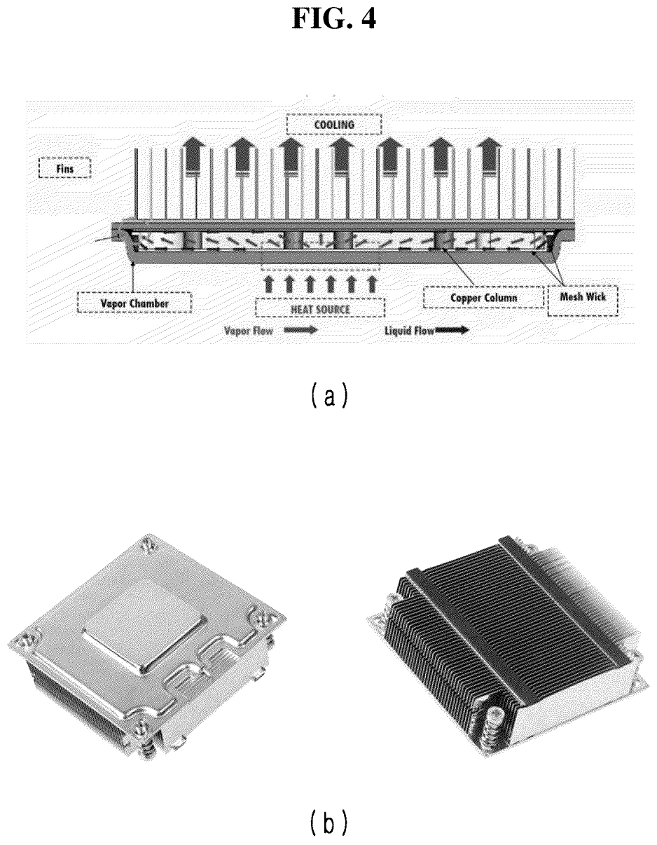

FIG. 5 is a structural diagram of a vapor chamber according to other conventional examples.

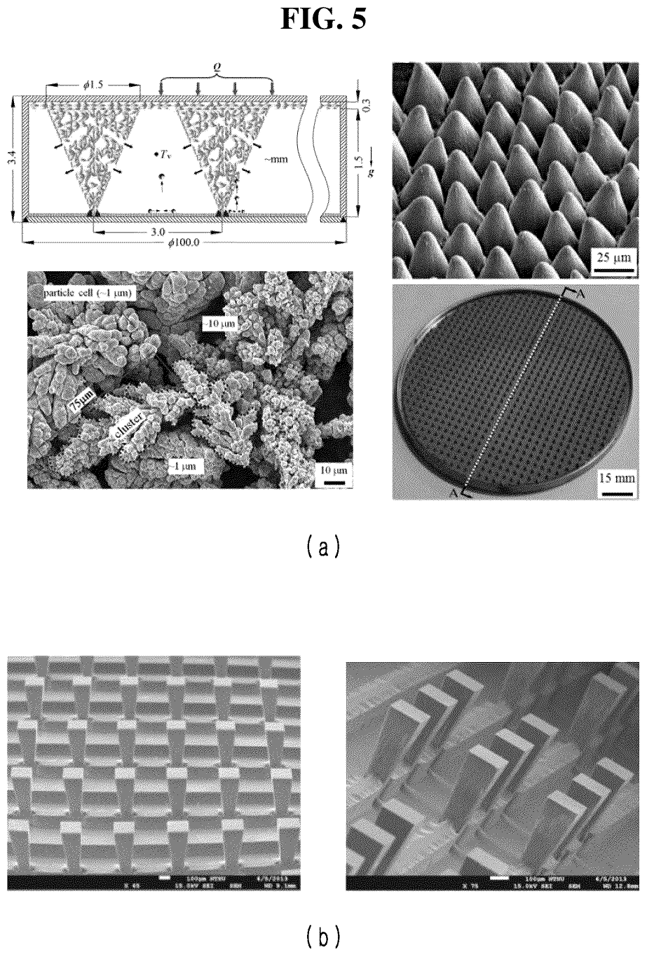

FIG. 6 is a schematic diagram illustrating the manufacturing process of a capillary-driven heat pipe according to another conventional example, and a product comparison photograph.

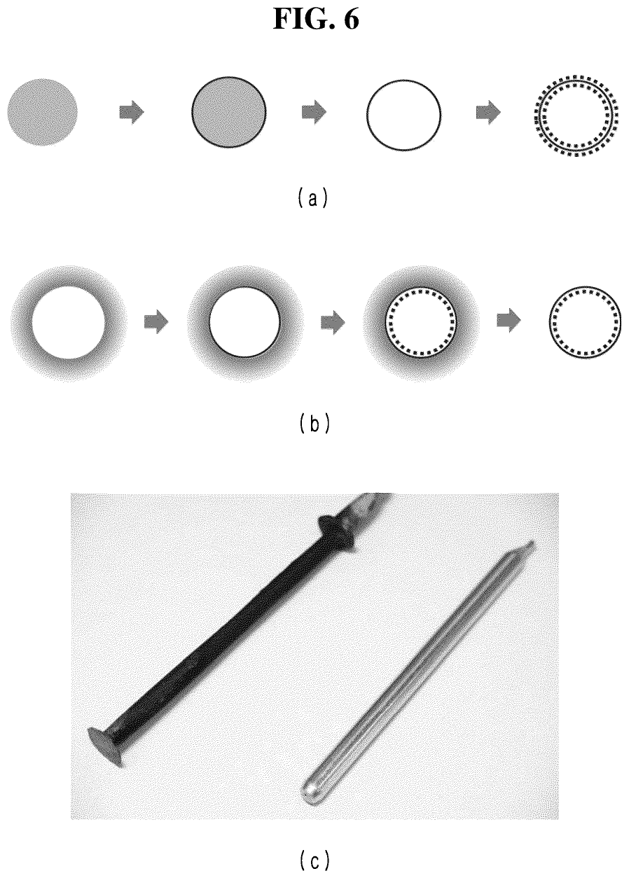

FIG. 7 is a sample photograph of a heat management medium according to one embodiment of the present disclosure.

FIG. 8 is a structural diagram and sample photograph of an open-type foam metal made of copper material according to one embodiment of the present disclosure.

FIG. 9 is a device and method for measuring the water absorption capacity of an open-type foam metal after hydrophilic treatment, and a comparative graph regarding the water absorption capacity.

FIG. 10 is a conceptual diagram of the overall process for manufacturing a heat management medium, including a method of using a plating layer to form a thin film envelope according to one embodiment of the present disclosure.

FIG. 11 is a graph illustrating the temperature change of a heat management medium according to the temperature change of a heat source, comparing when the amount of working fluid is changed according to one embodiment of the present disclosure.

FIG. 12 is a diagram illustrating a method for measuring heat transfer characteristics of a heat management medium manufactured as a rod-shaped specimen according to one embodiment of the present disclosure and the results thereof.

FIG. 13 is a diagram comparing the specifications and characteristics of a heat management medium manufactured as a flat plate specimen according to one embodiment of the present disclosure and a conventional flat-plate vapor chamber.

FIG. 14 is a diagram illustrating the product appearance and heat transfer characteristics of a heat management medium manufactured as a hexahedral specimen according to one embodiment of the present disclosure.

FIG. 15 is a graph illustrating the change in temperature of the specimen over time when the amount of working fluid injected in the specimen of FIG. 14 is changed.

FIG. 16 is a schematic diagram of a flat heat management medium that may be used as a casing structural material according to another embodiment of the present disclosure.

### DETAILED DESCRIPTION

Hereinafter, the present disclosure will be described in detail through examples. Prior to this, it should be noted that the terms or words used in the present specification and claims should not be interpreted as limited to their conventional or dictionary meanings, and should be interpreted with meanings and concepts that conform to the technical spirit of the present disclosure, based on the principle that the inventor may appropriately define the concept of the term to best explain his or her disclosure. Therefore, the configuration of the embodiments described in this specification is only one of the most preferred embodiments of the present disclosure and does not represent the entire technical spirit of the present disclosure. Therefore, it should be understood that various equivalents and modified examples may be substituted for them at the time of filing of the present disclosure. Meanwhile, in the drawings, identical or equivalent parts are given the same or similar reference numerals, and also, throughout the specification, when a part is said to “include” a certain component, this does not mean that other components are excluded, but that other components may be included, unless specifically stated otherwise.

### (Structure and Operation of Heat Management Medium)

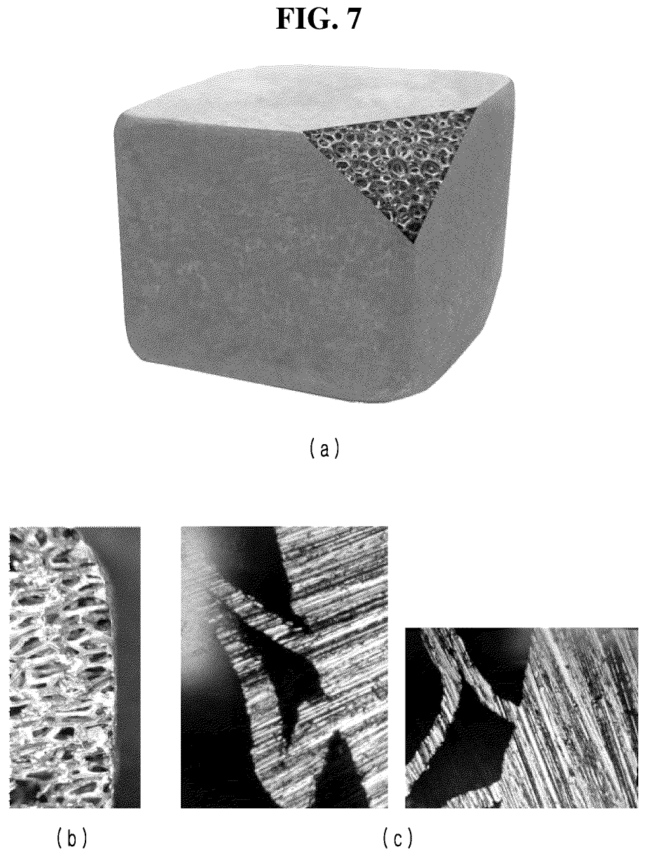

FIG. 7, (a) illustrates a sample of a heat management medium according to one embodiment of the present disclosure. Here, an open foam material is used as an example of an open porous material. The heat management medium includes an open porous material with a hydrophilic treatment on the pore surface, a thin film envelope attached to the outside of the open porous material to seal the open porous material in a vacuum state, and a working fluid injected into the pores of the open porous material. In this case, the amount of the working fluid injected may be changed so that the working fluid occupies 10 to 80% of the internal space, or the like, the internal space partitioned by the thin film envelope. The materials of the open porous material and the envelope are not particularly limited and may be composed of the same or different materials, and preferably, may be composed of a metal material with excellent thermal conductivity, such as copper. Referring to FIG. 7, (b) and (c), it may be confirmed that the open foam material and the envelope are well attached to each other.

### Hydrophilic Treated Open Porous Material

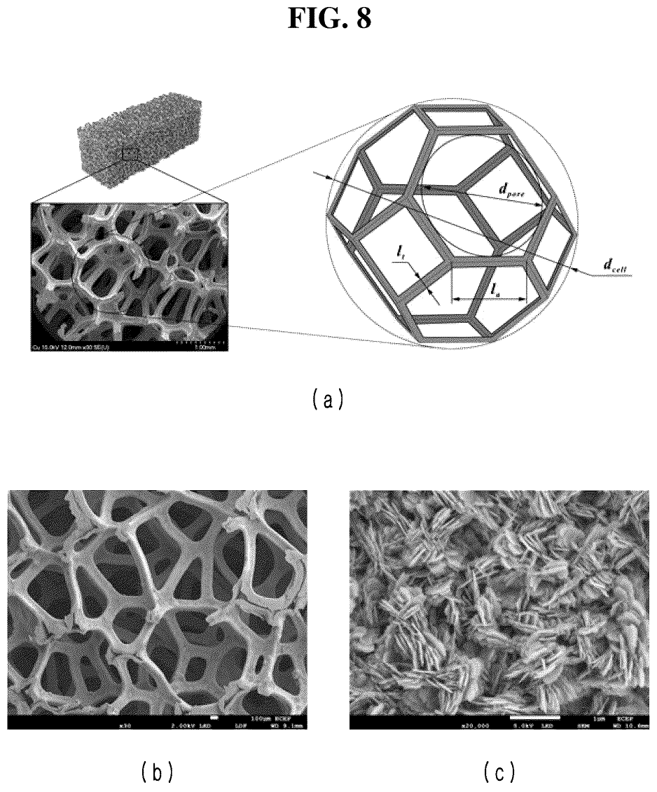

FIG. 8 illustrates a structural diagram and a sample photograph of an open-type foam metal made of copper material according to one embodiment of the present disclosure. Here, open-cell copper foam, which is one of open porous materials, was used. Referring to FIG. 8, (a), the open-cell copper foam preferably has a porosity of 90% or more and a pore size (dₚₒᵣₑ) of about 0.3 to 1.5 mm. When the porosity is less than 90%, the weight increases insignificantly, which is not desirable. However, although a larger porosity is advantageous for weight reduction, when it is extremely large, for example, 99% or more, and the yield strength is lower than 0.1 MPa, the material may collapse and narrow due to the pressure caused by the vacuum created inside, which is not desirable. In addition, when the pore size exceeds 1.5 mm, the capillary force of the open porous material will not be sufficiently high even after the hydrophilic treatment, making it insufficient as the movement passageway for liquid fluid, that is, a wick. On the other hand, when the pore size is less than 0.3 mm, the flow resistance of the gaseous working fluid will increase, which is not desirable. However, these porosity and pore size are limited only when water is used as a working fluid in the copper foam metal, and may vary depending on the type and microstructure of the open porous material and the type of working fluid.

To increase the hydrophilicity of the above copper open-cell foam, the surface was immersed in an aqueous solution of K₂S₂O₈ (1.5 g/L) and NaOH (7.5 g/L) for 24 hours to form cupric oxide (CuO) on the surface (Reference [8] Jingchun Min, Xiaomin Wu, Lifeng Shen, Frank Gao, Hydrophilic treatments of copper finned tube evaporators. International Refrigeration and Air Conditioning Conference at Purdue, Jul. 14-17, 2008). This treatment is called blackening treatment because the surface turns black after the treatment. FIG. 8, (b) and (c) illustrate the microstructure after the hydrophilic treatment.

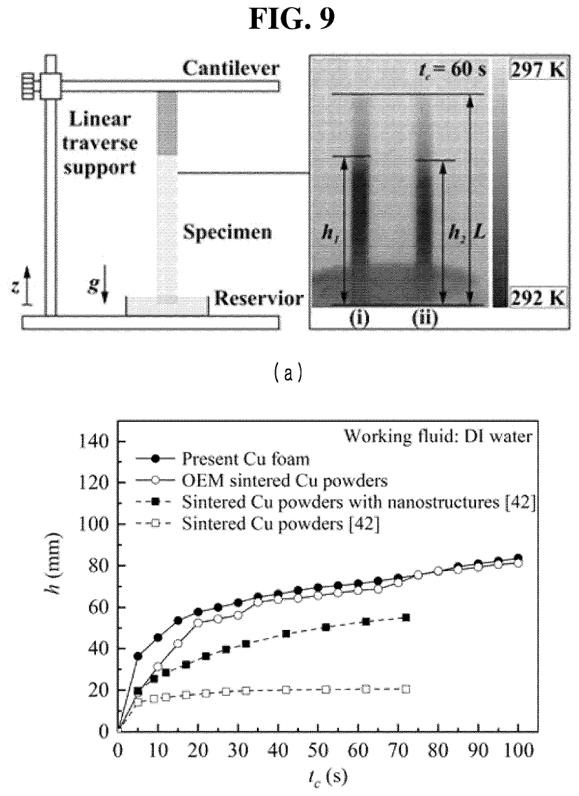

FIG. 9 illustrates an apparatus and method for measuring the water absorption capacity of a hydrophilic treated material, specifically, a rod-shaped hydrophilic treated open-cell foam metal (FIG. 9, (a)), and a comparative graph regarding the water absorption capacity (FIG. 9, (b)). Referring to FIG. 9, (b), it may be confirmed that the open-cell copper foam material of the present disclosure has a superior water absorption capacity over time compared to the conventional copper powder sintered body, even though the pore size is 0.713 mm, which is much larger than the pore size of 20 to 50 μm of a copper powder sintered body widely used as a conventional wick (Reference [9] K. Leong, C. Liu, G. Lu, Characterization of Sintered Copper Wicks Used in Heat Pipes. Journal of Porous Materials 4, 303-308 (1997).)

In the embodiment, the open foam material was used as an example of the open porous material, but other porous materials having a similar pore size but a different microstructure may be used. For example, a microarchitectural material or a three-dimensional truss-shaped porous material (reference [10] Fleck, N. A., Deshpande, V. S. & Ashby, M. F. Micro-architectured materials: past, present and future. Proc. R. Soc. A 466, 2495-2516 (2010).), a woven metal (reference [11] K. J. Kang, “Wire-woven cellular metals: the present and future”, Progress in Materials Science, Vol. 69, pp. 213-307, 2015) or a woven metal material may be used instead of the open foam material according to the embodiment.

The heat management medium according to one embodiment of the present disclosure may function as a storage and transport medium for traditional liquid working fluids as well as a transport medium for gaseous working fluids because the pores of the open porous material have a predetermined, uniform size and are surface-hydrophilic treated. Accordingly, each function of the heat management medium, such as exchange, transmission, absorption, and storage, is autonomously determined according to the operating environment related to the size and appearance of the heat management medium, the amount and location of heat input, or the like, so that the usability of the internal space of the heat management medium is optimized and maximized, and since there is no need to design each part of the heat management medium differently or separately for each function, the degree of freedom in product design is high.

### Thin Film Envelope

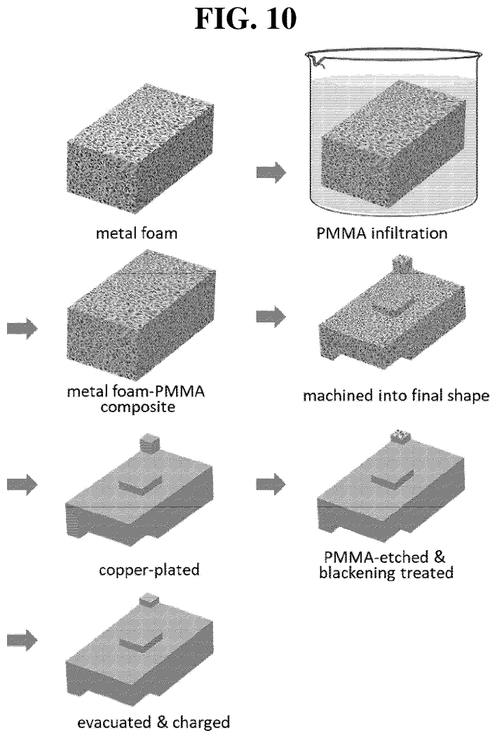

According to one embodiment of the present disclosure, the envelope of the heat management medium may be formed of, for example, a copper metal having a thickness of several tens of micrometers. For example, a method of forming the envelope may include attaching a thin plate to the outer surface of the open porous material using a traditional manufacturing process such as resin bonding, welding, soldering, or brazing, and sealing the edges of the thin plate. Furthermore, as another practical method of forming the envelope, as illustrated in FIG. 10, the open porous material may be impregnated with a resin solution and cured, and then, the insides of the pores are filled with the resin solution. Thereafter, by forming the plating layer on the outer surface of the open porous material in this state, and then finally removing the cured resin within the pores, thereby forming the plating layer as the envelope. In this case, the cured resin, which is a temporary filler, may be selectively removed by etching, dissolving, or the like, by removing a portion of the plating layer by a method such as polishing, in a state where a portion of the cured resin, together with the open porous material inside, is exposed to the outside.

Meanwhile, FIG. 10 illustrates an overall process conceptual diagram regarding the manufacturing process of the heat management medium, including a method of using the plating layer in forming the thin film envelope. That is, the heat management medium composed of the plating layer as the envelope may be manufactured through a series of processes sequentially along the left, right, top, and bottom directions of the drawings, that is, manufacturing the open porous material, impregnating the open porous material with a resin solution (for example, PMMA), curing, shaping/processing the outer shape of the open porous material, forming a plating layer (envelope) on the outer surface of the open porous material, removing the internal cured resin (PMMA) and performing hydrophilic treatment (blackening treatment), forming an internal vacuum, and injecting a working fluid.

The heat management medium according to the present disclosure has a very thin envelope, enabling rapid heat transfer to the outside through conduction. In addition, the heat management medium may be implemented as an extremely lightweight structural material by having a structure in which the outer surface of the open porous material is surrounded by a thin envelope. Despite this, the numerous thin ligaments interconnected within the open porous material act as a kind of truss-shaped support element against external force applied from the outside, thereby ensuring sufficient structural strength to withstand high internal vacuum pressure and external load. Accordingly, even though the heat management medium has a two-dimensional flat plate-like outer shape similar to a conventional vapor chamber, unlike a conventional vapor chamber, there is no need to provide separate support elements such as pillars or columns inside to prevent collapse or constriction due to high internal vacuum pressure, thereby simplifying manufacturing and allowing freedom in the external shape of the product.

### Excessive Working Fluid and Motion

In the present disclosure, the type of working fluid is not particularly limited, such as distilled water, and the amount of working fluid injected inside may also preferably be in a state where, for example, 10 to 80% of the internal space is filled, and accordingly, the heat management medium according to the present disclosure may operate regardless of the amount of working fluid.

In the present disclosure, functions such as heat exchange, transfer, absorption or storage, and shock absorption are performed by the working fluid, and each of these functions or roles is characterized in that it is determined autonomously or automatically from the configuration of a uniform microstructure having a predetermined pore size of the open porous material and a hydrophilic treatment of the pore surface as described above.

That is, a portion of the working fluid may serve as a first medium that rapidly transfers heat by vaporizing in a high-temperature region near a heat source, moving to a low-temperature region near a cold source, condensing, and returning to the high-temperature region by capillary action to repeat the same cycle, as in a typical heat pipe, and the remainder of the working fluid may serve as a second medium that stores a large amount of heat energy by utilizing a high specific heat.

In this case, the amount and distribution of the working fluids that play the role of the first medium and second medium are automatically or autonomously controlled. For example, as the heat energy transferred from the outside increases, the internal temperature and the temperature of the working fluid rise, so that the fraction of the second medium in the working fluid decreases while the fraction of the first medium increases accordingly. Furthermore, when heat energy exceeding a critical value is introduced, all of the working fluids operate as the first medium, and if necessary, an additional cooling device may be required externally. Conversely, when the heat energy transferred from the outside decreases, the fraction of the second medium increases, so that the roles of the working fluids may be automatically controlled.

Therefore, in the case of the heat management medium of the present disclosure, since an excessive amount of working fluid may be filled, even when excessive heat is momentarily generated and input, a portion of the working fluid is easily and quickly absorbed through the specific heat and latent heat (heat of vaporization) in the process of being heated and vaporized, thereby effectively alleviating or suppressing the rapid temperature rise and resulting thermal shock in the heat source and the heat management medium, and as a result, the demand for or operation of an additional cooling device may be minimized.

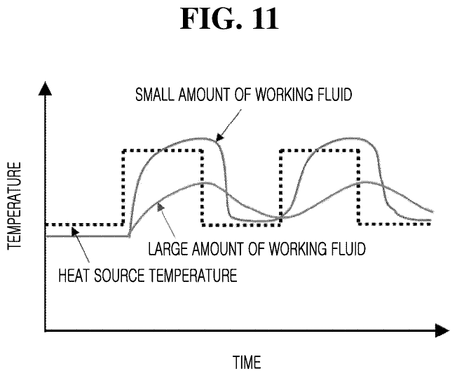

FIG. 11 is a graph illustrating the temperature change of a heat management medium according to the temperature change of a heat source, comparing cases where the amount of working fluid is varied according to one embodiment of the present disclosure. Referring to FIG. 11, it may be seen that as the amount of working fluid increases, the amount of working fluid performing the second role based on the heat management medium increases, and the heat capacity also increases, thereby enhancing the function of mitigating thermal shock.

### (Example of Individual Implementation and Operation Using Heat Management Medium)

Hereinafter, examples of applying the heat management medium of the basic configuration described above in various external forms according to each purpose or usage environment, and the corresponding operation contents and performance are described in more detail.

### When Manufactured in Shape of Conventional Bar-Shaped Heat Pipe or Flat-Plate Vapor Chamber

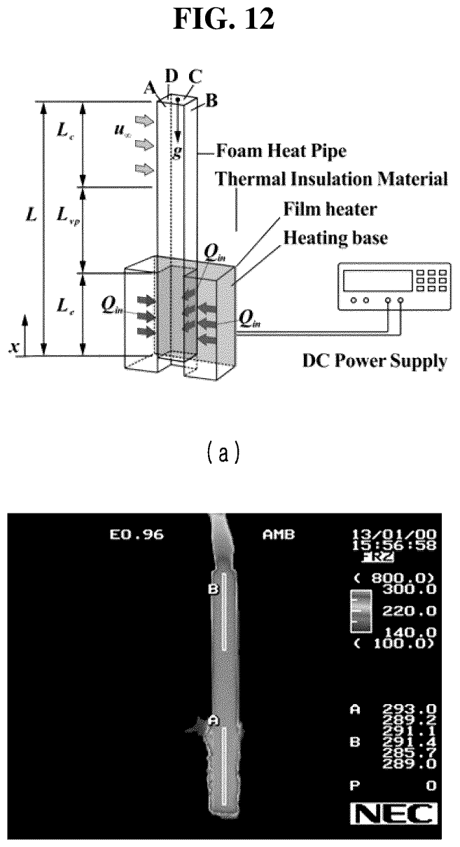

FIG. 12 illustrates a method for measuring thermal conductivity characteristics of a heat management medium manufactured as a rod-shaped specimen according to one embodiment of the present disclosure and the results thereof. Referring to FIG. 12, (a), a heat management medium specimen according to one embodiment was manufactured as a long rod with a square cross-section, and the temperature distribution of the specimen was measured using an infrared imaging camera so that heat was introduced from the bottom of the specimen and transferred to the top. Referring to FIG. 12, (b), the temperature distribution in the vertical longitudinal direction of the specimen is very uniform, which indicates that the specimen functions well as a heat pipe.

The difference between the heat management medium specimen manufactured in a rod shape according to FIG. 12 and the conventional heat pipe is that the envelope is very thin with a thickness of several tens of μm and has a square cross-section shape rather than a circular cross-section shape, which is disadvantageous for supporting a vacuum, but it is structurally very strong. Moreover, like a traditional wick among open porous materials, a part that functions or acts as a storage and movement passageway for a liquid working fluid and another part that acts as a movement passageway for a gaseous working fluid are autonomously determined according to the operating environment, and also because there is a sufficient amount of excess working fluid, even when an excessive amount of heat is momentarily overloaded, the dry-out or depletion of the working fluid may be effectively delayed or suppressed.

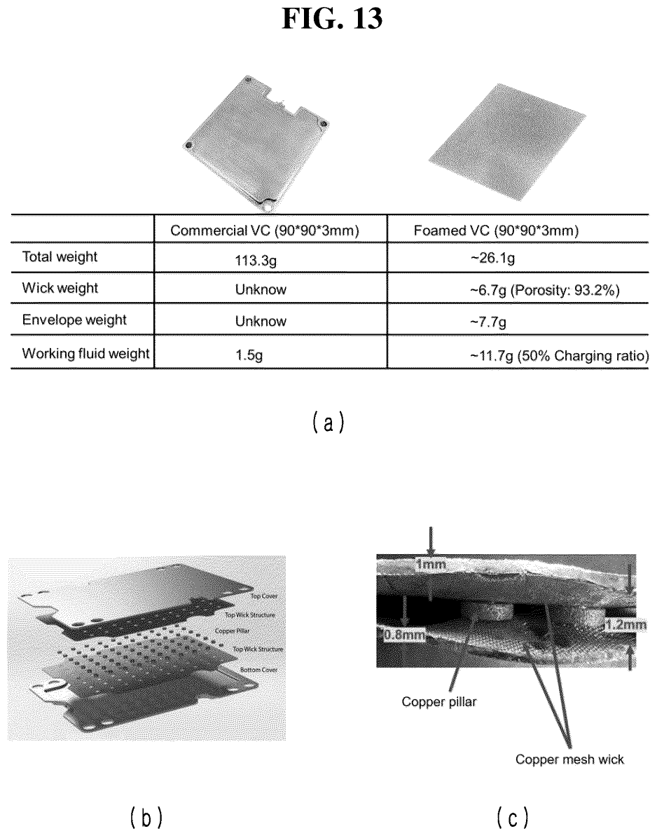

Meanwhile, when the heat management medium according to the present disclosure is manufactured in the form of a thin plate, it is expected to provide a medium similar to the conventional vapor chamber that operates in the same manner as in FIG. 12 above. For example, when a specimen is manufactured based on the basic configuration of the heat management medium of the present disclosure, and the specimen has the same specifications of 90 mm×90 mm×3 mm in length×width×height as a commercial vapor chamber (Wakefield-Vette, VC-90-90-3), the expected weight of the specimen is 26 g as illustrated in FIG. 13, (a), which may be significantly reduced to about 20% of the conventional standard. However, since the working fluid is filled 7 times or more, the allowable heat input is also expected to be significantly larger. FIG. 13, (b) illustrates a structural diagram of a conventional vapor chamber similar to the flat heat management medium of the present disclosure, and FIG. 13, (c) illustrates an exploded photograph of an actual product, and it is confirmed that FIG. 13, (b) and (c) are very similar.

The reason why the conventional commercial vapor chamber product is heavy is because, although the conventional commercial vapor chamber product has a plate shape, the upper and lower envelopes should be relatively thick at 1 mm and 0.8 mm to withstand the compression caused by a vacuum, and also, the interior should be equipped with a large number of support elements such as copper pillars. Accordingly, in the case of conventional commercial vapor chambers, the internal space where the working fluid may be accommodated and used is only about 1.2 mm in height, and it is clear that the amount of liquid working fluid that may be absorbed by the metal (copper) wick in the form of a wire mesh disposed on the upper and lower inner sides of the internal space is bound to be greatly reduced.

### When Manufactured in External Shape Similar to 3D Hexahedron

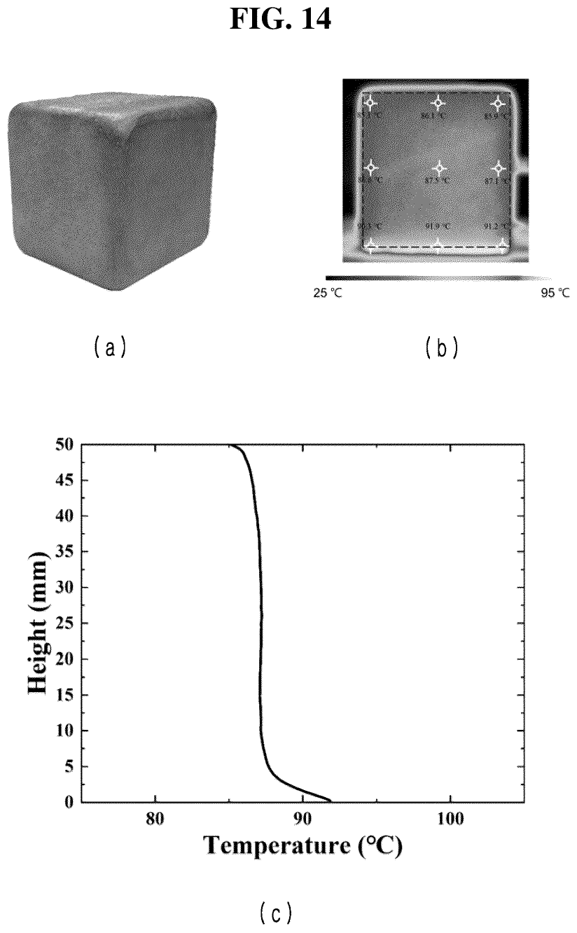

FIG. 14 is a diagram illustrating the product appearance and heat transfer characteristics of a heat management medium manufactured as a hexahedral specimen according to one embodiment of the present disclosure. Referring to FIG. 14, (a), the specimen was manufactured in the shape of a cube with a side length of 50 mm, and after forming the envelope with a copper plating layer, a nickel alloy was additionally plated to facilitate soldering and brazing. Since the volume of the internal space of the specimen is maximized compared to the surface area of the specimen, it is particularly useful for investigating its role as a second medium for storing the aforementioned heat energy. FIG. 14, (b) and (c) illustrate a thermal image and a graph, respectively, of the temperature distribution when 20 W of heat is input from the lower surface in a state where 20% of the internal space is filled with water as the working fluid. The temperature distribution is very consistent over most of the specimens except for the surface in contact with the heat source and the ambient air, confirming that the specimen exhibits excellent heat transfer characteristics, similar to the conventional heat pipe.

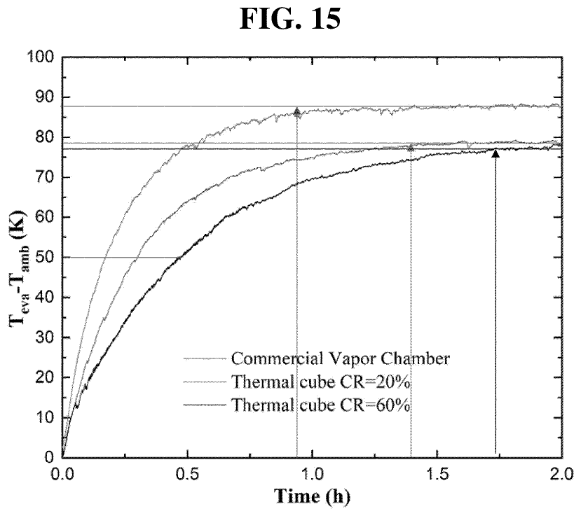

FIG. 15 illustrates the temperature change of the specimen over time when the amount of working fluid injected into the specimen of FIG. 14 is changed. Specifically, FIG. 15 illustrates the temperature change of the bottom face of the specimen over time after a heat input of 20 W was applied to the bottom face of the cubic specimen of FIG. 14 when the amount of working fluid water was filled to 20% and 60% of the internal volume, respectively.

It may be confirmed that the temperature rise rate is significantly reduced in the case where 60% water is filled compared to the case where 20% water is filled. Accordingly, in the former case, the temperature stabilizes at T_{steady}=79° C. after 1.4 hours, whereas in the latter case, the temperature is still lower than 79° C. at T_{steady}=77° C. even after 2 hours. In addition, the results of measuring the temperature when the same heat is input to the commercial vapor chamber in FIG. 13 as a comparison subject are illustrated. It may be seen that, unlike the cubic specimen according to the present disclosure, the bottom temperature increases at a much faster rate and reaches a much higher 85° C. after 1 hour.

The hexahedral heat management medium according to FIGS. 14 and 15 may rapidly increase the fraction of the working fluid that acts as the second medium in proportion to the cube of the length as the length of one side increases, so that the amount of heat input that may be absorbed by the high specific heat and latent heat is greatly increased, and as a result, the time to reach the saturation temperature is extended. Therefore, it may be particularly useful for the purpose of mitigating thermal shock in the event of an instantaneous overheating input, as in FIG. 11. However, since the surface area of a specimen of this shape is relatively small, natural and forced convection cooling using additional cooling fins and fans may be required when a high heat input is continuously applied.

In addition, the hexahedral heat management medium according to FIGS. 14 and 15 is composed of an envelope with a thickness of several tens of μm, the open foam material with a porosity of 90% or more, and the working fluid, and is therefore very light relative to the volume. For example, in the case of a copper heat management medium having a hexahedral shape with one side of 50 mm as above, when the copper heat management medium is composed of the envelope with the thickness of 50 μm, the open foam material with the porosity of 95%, and 50% of the internal space filled with working fluid water, the total weight is approximately 124.8 g, which is only 37% of 337.5 g which is the bulk weight of aluminum of the same volume, and the weight relative to the volume is very low.

When Used in Combination with Casing Structure

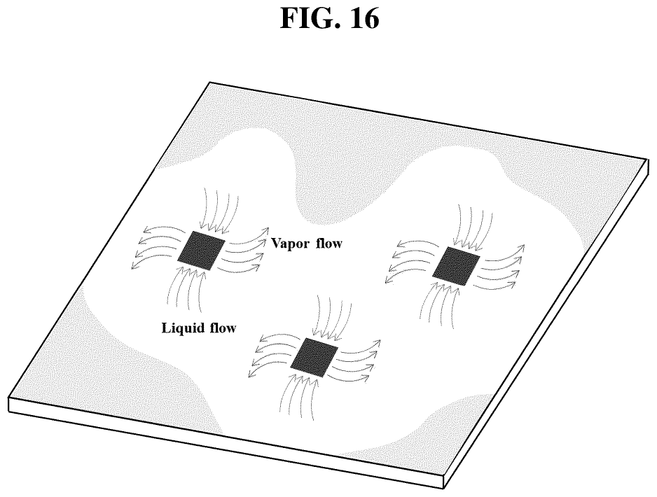

FIG. 16 is a schematic diagram of a flat heat management medium that may be used as a casing structural material according to another embodiment of the present disclosure. The structural material may be, for example, a typical structural sandwich plate having rigid face materials on the upper and lower parts and a porous material in the middle, as an ultra-light casing structural material used in mobile devices. Such a casing structural material may be required to protect internal components or systems, as well as to transfer and dissipate heat generated from a plurality of component elements to the outside. Since the heat management medium according to the present disclosure has excellent structural and thermal management characteristics, it may be very suitable for such use when manufactured in a large-area, flat-plate shape. FIG. 16 illustrates a state of use of a large-area, flat-plate heat management medium that operates in a state where a plurality of components that function as heat sources are in contact with one surface thereof, for such use. Around each heat source, heat exchange and transfer occur as in the vapor chamber, and the amount, range, and distribution of the working fluid that functions as the first medium mentioned above are determined. In this case, when there is an excess of working fluid, a significant proportion of the working fluid functioning as a second medium may also be present. Meanwhile, when the heat management medium according to the present disclosure is used as a structural material such as a casing, the problem of reduced usability and stability due to sloshing of the internal working fluid may be effectively prevented by the complex and irregular microstructure of the open microstructure.

The above description relates to specific embodiments of the present disclosure. As described above, the above embodiments according to the present disclosure are disclosed for illustrative purposes and are not to be construed as limiting the scope of the present disclosure. It should be understood that various changes and modifications are possible for those skilled in the art without departing from the essence of the present disclosure. Accordingly, all such changes and modifications may be understood to fall within the scope of the disclosure disclosed in the claims or their equivalents.

1. A heat management medium having functions of heat exchange, transfer, absorption or storage, and shock absorption, the heat management medium comprising:
an open porous material with a hydrophilic treatment on a pore surface;
a thin film envelope attached to the outside of the open porous material to seal the open porous material in a vacuum state; and
a working fluid filling pores of the open porous material,
wherein the open porous material has a structure that completely fills an internal space partitioned by the thin film envelope, and simultaneously acts as a moving medium for liquid and gaseous working fluids.

2. The heat management medium of claim 1, wherein 10 to 80% of the internal space partitioned by the thin film envelope is filled with the working fluid in a liquid state.

3. The heat management medium of claim 1, wherein the open porous material is any one of an open foam metal, a microarchitectural material, a three-dimensional truss-shaped porous material, or a woven metal material.

4. The heat management medium of claim 3, wherein the working fluid is water, and the open porous material is a foam metal having a porosity of 90% or more.

5. The heat management medium of claim 3, wherein the working fluid is water, and the open porous material is a foam metal having a pore size of 0.3 to 1.5 mm.

6. The heat management medium of claim 1, wherein the envelope is a thin plate attached by means of resin bonding, welding, soldering, or brazing.

7. The heat management medium of claim 1, wherein the envelope is formed by a plating layer formed on the outer surface of the open porous material in a state of filling pores of the open porous material with a temporary filler made of a polymer material, and the temporary filler is removed after the plating layer is formed.

8. The heat management medium of claim 1, wherein the envelope is made of metal.
